(19) United States
(12) Patent Application Publication
(10) Pub. No.: US 2025/0208424 A1
(43) Pub. Date: Jun. 26, 2025

(54) Optical Waveguide Structure and Fabrication Method thereof, Optical Component, and Near-Eye Display Device

(71) Applicant: Huawei Technologies Co., Ltd., Shenzhen (CN)

(72) Inventors: Wuwen Ding, Dongguan (CN); Peng Sun, Shenzhen (CN); Lulu Zhu, Dongguan (CN); Jianhan Yang, Shanghai (CN); Xiaoyu Zhao, Shenzhen (CN); Qi Liu, Dongguan (CN); Zhuoyong Deng, Dongguan (CN); Junnan Jiang, Shenzhen (CN); Yunkai Lu, Dongguan (CN); Yanjun Guo, Dongguan (CN)

(21) Appl. No.: 19/073,571

(22) Filed: Mar. 7, 2025

Related U.S. Application Data
(63) Continuation of application No. PCT/CN2023/117571, filed on Sep. 7, 2023.

(30) Foreign Application Priority Data
Sep. 8, 2022 (CN) 202211092291.2
Dec. 30, 2022 (CN) 202211731720.6

(51) Int. Cl. G02B 27/01; G02B 6/26; G02B 6/34; G02B 27/00

(52) U.S. Cl. CPC G02B 27/0172; G02B 6/262; G02B 6/34; G02B 27/0018; G02B 27/0176; G02B 2027/015; G02B 2027/0174; G02B 2027/0178

(57) ABSTRACT

An optical waveguide includes a grating structure having an end face and core structures having a first refractive index and sequentially arranged at intervals in a vector direction and each having a connection end coupled to a waveguide substrate, a free end disposed opposite to the connection end in a height direction, and a side surface disposed between the connection end and the free end. A first film structure has a second refractive index unequal to the first refractive index, a film body configured to wrap the side surface, first and second film body ends, a first end part disposed at the first film body end and coupled to the waveguide substrate, and a second end part disposed at the second film body end and that is coplanar with the free end. The free ends of the core structures and second end part jointly define the grating structure end face.

### CROSS-REFERENCE TO RELATED APPLICATIONS

This is a continuation of International Patent Application No. PCT/CN2023/117571 filed on Sep. 7, 2023, which claims priority to Chinese Patent Application No. 202211092291.2 filed on Sep. 8, 2022 and Chinese Patent Application No. 202211731720.6 filed on Dec. 30, 2022, all of which are hereby incorporated by reference in their entireties.

### TECHNICAL FIELD

This disclosure relates to the field of optical display technologies, and in particular, to an optical waveguide structure and a fabrication method thereof, an optical component, and a near-eye display device. The optical waveguide structure may be a grating structure, an out-coupling grating, an optical waveguide structure having a grating structure, or the like. The optical component may be an optical engine, a light combining unit, an optical component having an optical engine and a light combining unit, or the like.

### BACKGROUND

Near-eye display, also referred to as head-mounted display or wearable display, can be used to create a virtual image in a single-eye or dual-eye field of view. The near-eye display is a technology that uses a display device placed within a non-visible distance of human eyes to render light field information for the human eyes, thereby reconstructing a virtual scene in front of the human eyes.

Augmented reality (AR) is a new technology that “seamlessly” integrates real-world information and virtual-world information. It uses optics, computers, electronics, and the like to simulate and superimpose physical information (such as visual information, three-dimensional (3D) appearance, sound, taste, and tactile sense) that is difficult to experience in a particular time and space range of the real world. Both the real-world information and the virtual information are displayed simultaneously, with the two types of information complementing and augmenting each other. In visual AR, a user combines a real world with a virtual image by using an optical display apparatus, to have an immersive visual experience of virtual-real combination.

The AR technology is applied to a near-eye display device, so that AR glasses are generated. The AR may implement many functions, and may be considered as a miniature mobile phone, and a status of the user can be determined by tracking a line-of-sight track of an eyeball, and a corresponding function may be enabled. A near-eye display technology product (for example, AR glasses) is developing toward a lighter, thinner, and more portable direction, and content rendered by the near-eye display device accordingly needs to be more comfortable, more authentic, and more smooth. Therefore, for the near-eye display device, an industry design development trend is lightweight design, thin and small-sized design, improved optical display effect, and the like.

### SUMMARY

This disclosure provides an optical waveguide structure and a fabrication method thereof, an optical component, and a near-eye display device. The optical waveguide structure may be a grating structure, an out-coupling grating, an optical waveguide structure having a grating structure, or the like. The optical component may be an optical engine, a light combining unit, an optical component having an optical engine and a light combining unit, or the like. In this way, the near-eye display device can be lightweight and thin, and have a small size, and an optical display effect can be improved.

According to a first aspect, this disclosure provides an optical waveguide, including a waveguide substrate and a grating structure formed on the waveguide substrate. The grating structure includes a plurality of core structures and a film structure. A refractive index of the film structure is different from a refractive index of the core structure, the plurality of core structures is sequentially arranged at intervals in a vector direction of the grating structure, each core structure includes a connection end, a free end, and a side surface, the connection end is connected to the waveguide substrate, the free end and the connection end are disposed opposite to each other in a height direction of the core structure, and the side surface is connected between the connection end and the free end. The film structure includes a film body, a first end part, and a second end part, the film body wraps the side surface of the core structure, the first end part and the second end part are respectively located at two ends of the film body, the first end part is connected to the waveguide substrate, the second end part and the free end of the core structure are coplanar, and the free ends of all the core structures and the second end part of the film structure jointly form an end face of the grating structure.

In this solution, diffraction efficiency and optical utilization are improved through variation of refractive indexes of a grating. Further, diffraction efficiency and optical utilization are improved by using different refractive indexes of the core structures and the film structures of the grating structure. The free end of the core structure and the second end part of the film structure jointly form the end face of the grating structure, so that diffraction efficiency of the grating structure is better. The grating structure has the core structure and the film structure with different refractive indexes only in the vector direction of the grating structure. In a height direction of the grating structure, because both the free end of the core structure and the second end part of the film structure are in an exposed state at a position of the end face of the grating structure, that is, the exterior of the core structure in the height direction is not wrapped by the film structure, diffraction efficiency of the grating structure can be ensured. If the free end of the core structure is wrapped by the film structure, a part that is of the film structure and that wraps the free end of the core structure generates a diffraction effect in the height direction of the grating structure. However, because diffraction in the height direction of the grating structure has a direction different from the vector direction of the grating structure, diffraction in the vector direction of the grating structure is negatively affected, that is, diffraction efficiency of the grating structure is reduced.

In a possible implementation, an end face of the free end of the core structure and an end face of the second end part of the film structure are coplanar. In the grating structure provided in this solution, the end face of the free end and the end face of the second end part are coplanar. The film structure may be fabricated by coating the core structure, and a film structure on a surface of the grating structure may be polished to be flat by using a process such as chemical mechanical polishing (CMP), to implement a coplanar structure. The coplanar structure provided in this solution is easy to implement and has low fabrication costs.

In a possible implementation, between adjacent core structures, the film structure includes at least three film layers, the at least three film layers are disposed in a stacked manner between the side surfaces of the adjacent core structures, the at least three film layers have different refractive indexes, and along the vector direction of the grating structure, refractive indexes of the at least three film layers exhibit a gradient trend of sine distribution. The grating with a sine gradient refractive index provided in this solution may have higher diffraction efficiency and a narrower full width at half maximum, and can meet a modulation requirement of incident efficiency at a specific angle, thereby improving light efficiency of an entire system.

In a possible implementation, between the adjacent core structures, the at least three film layers have different thicknesses.

A film layer with a largest thickness is adjacent to the core structure, and a thickness of the core structure is greater than that of the film layer with the largest thickness, or a film layer with a smallest thickness is adjacent to the core structure, and a thickness of the core structure is less than that of the film layer with the smallest thickness. In this solution, different refractive indexes are achieved by using differentiated thickness design.

In a possible implementation, one of the film layers includes multiple layers of first sub-films and multiple layers of second sub-films that are alternately arranged in one-to-one correspondence, a refractive index of the first sub-film is N1, a refractive index of the second sub-film is N2, a refractive index of the film layer that includes the multiple layers of first sub-films and the multiple layers of second sub-films is N, and N1<N<N2. This solution provides a film layer refractive index modulation solution. A film layer that meets a condition is obtained by disposing multiple layers of first sub-films and multiple layers of second sub-films that are alternately arranged, and there is a plurality of fabrication processes, which has an advantage of easy implementation.

In a possible implementation, a part of the film structure between the adjacent core structures is a seamless structure. It may be understood that space between the adjacent core structures is filled by the film structure, and no gap is left. There is no gap inside the grating structure provided in this solution, so that diffraction efficiency of the grating structure is not easily affected by an environmental factor.

In a possible implementation, there is a gap in a middle position of the film structure between the adjacent core structures. This solution provides a solution in which there is a gap between the core structures, so that a refractive index can be modulated by using air, a fabrication process can be simplified, and costs can be reduced.

In a possible implementation, refractive indexes of any positions in the core structure are the same. This solution helps ensure stability of diffraction efficiency of the grating structure.

In a possible implementation, the core structure is formed on the waveguide substrate by using a nano-imprinting process or an etching process, and the film structure is fabricated by using a coating process. The coating fabrication process is easy to process in batches, and can improve fabrication efficiency of the grating structure.

In a possible implementation, a material of the core structure includes a metal oxide.

In a possible implementation, the optical waveguide includes an in-coupling grating, where the in-coupling grating includes a first in-coupling structure and a second in-coupling structure, the first in-coupling structure and the second in-coupling structure are disposed opposite to each other and are respectively located on a top surface and a bottom surface of the waveguide substrate, the first in-coupling structure and the second in-coupling structure have different grating tilt angles, and the grating structure is at least a part of the in-coupling grating. The first in-coupling structure and the second in-coupling structure may diffract light rays in different directions, so that more light rays are coupled into the waveguide substrate. That is, the first in-coupling structure and the second in-coupling structure are combined to achieve high diffraction efficiency within a large angle range.

In a possible implementation, each of the first in-coupling structure and the second in-coupling structure is the grating structure, a refractive index of a core structure of the first in-coupling structure is greater than a refractive index of a core structure of the second in-coupling structure, and a refractive index of a film structure of the first in-coupling structure is greater than a refractive index of a film structure of the second in-coupling structure. In this solution, the first in-coupling structure and the second in-coupling structure are restricted to have different refractive indexes, so that the in-coupling grating can diffract light with different angles or wavelengths.

In a possible implementation, an in-coupling grating and an out-coupling grating formed on the waveguide substrate are included. The out-coupling grating is the grating structure, the out-coupling grating includes a first region and a second region, and the first region is closer to the in-coupling grating than the second region. A refractive index difference between a core structure and a film structure of the out-coupling grating in the first region is a first value, a refractive index difference between a core structure and a film structure of the out-coupling grating in the second region is a second value, and the first value is less than the second value. This solution is used to modulate diffraction efficiency.

In a possible implementation, a relay grating is included. The relay grating is located between the in-coupling grating and the out-coupling grating, the relay grating is the grating structure, the relay grating includes a third region and a fourth region, the third region is closer to the in-coupling grating than the fourth region, a refractive index difference between a core structure and a film structure of the relay grating in the third region is a third value, a refractive index difference between a core structure and a film structure of the relay grating in the fourth region is a fourth value, the third value is less than the fourth value, and the fourth value is less than the first value. This solution is used to modulate diffraction efficiency.

In a possible implementation, the relay grating includes a first relay structure and a second relay structure, the first relay structure and the second relay structure are respectively disposed on a top surface and a bottom surface of the waveguide substrate, and the first relay structure and the second relay structure have different vector directions. This solution is used to modulate diffraction efficiency.

In a possible implementation, the first relay structure and the second relay structure each are the grating structure, and in the vector direction of the first relay structure, a refractive index difference between a core structure of the first relay structure and a film structure of the first relay structure gradually increases. This solution is used to modulate diffraction efficiency.

### BRIEF DESCRIPTION OF DRAWINGS

FIG. 1 is a diagram of a near-eye display device according to an implementation of this disclosure;

FIG. 2 is a diagram of a near-eye display device according to an implementation of this disclosure;

FIG. 3 is a diagram of the implementation shown in FIG. 1 or the implementation shown in FIG. 2 in another direction;

FIG. 4 is a planar diagram of a near-eye display device according to an implementation of this disclosure;

FIG. 5 is a diagram of an optical waveguide according to an implementation of this disclosure;

FIG. 6 is an exploded diagram of a part of a grating structure and a part of a waveguide substrate in FIG. 5;

FIG. 7 is a diagram of an end face of a grating structure of an optical waveguide according to an implementation of this disclosure;

FIG. 8 is a diagram of curves showing a correspondence between an incident angle and diffraction efficiency for comparison between a grating structure with sinusoidal gradient refractive index distribution and a grating structure with a homogeneous structure;

FIG. 9 is an exploded diagram of a part of a grating structure and a part of a waveguide substrate of an optical waveguide according to an implementation of this disclosure;

FIG. 10 is a diagram of a second film layer in a grating structure in an optical waveguide according to an implementation of this disclosure;

FIG. 11 is a diagram of fabricating a core structure on a waveguide substrate;

FIG. 12 is a diagram of three steps of completing fabrication of a grating structure on a basis of the structure shown in FIG. 11;

FIG. 13 is a diagram of a core structure and a film structure on a waveguide substrate of an optical waveguide according to an implementation of this disclosure;

FIG. 14 is a diagram of a grating structure on a waveguide substrate of an optical waveguide according to an implementation of this disclosure;

FIG. 15 is a 3D diagram of an optical waveguide according to an implementation of this disclosure;

FIG. 16 is a planar diagram of an optical waveguide according to an implementation of this disclosure;

FIG. 17 is a planar diagram of an optical waveguide according to an implementation of this disclosure;

FIG. 18 is a planar diagram of an optical waveguide according to an implementation of this disclosure;

### DESCRIPTION OF EMBODIMENTS

The following embodiments of this disclosure provide a near-eye display device. The near-eye display device may include but is not limited to an AR device. In a specific implementation, the near-eye display device provided in this disclosure is in a form of AR glasses, a head-mounted device, or the like. The following describes the near-eye display device in this disclosure by using an example in which the near-eye display device is AR glasses.

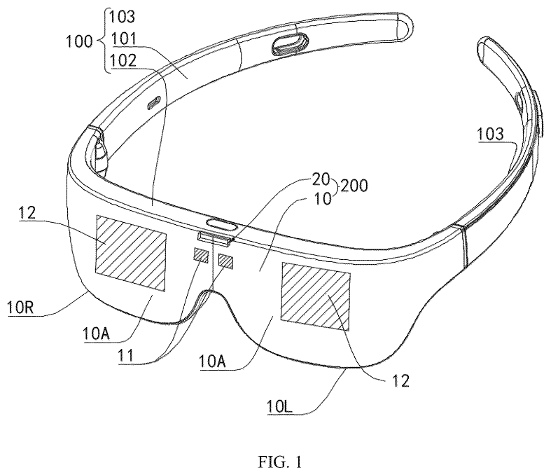

FIG. 1 is a diagram of a near-eye display device according to an implementation of this disclosure. As shown in FIG. 1, a near-eye display device 1000 includes a mechanical part 100 and an optical component 200. The mechanical part 100 is configured to construct an overall appearance architecture of the near-eye display device 1000 and mount an internal optical device and an internal electronic component. The optical component 200 is an optical device. The mechanical part 100 includes a frame 102 and a temple, and the temple includes a right temple 101 and a left temple 103. The right temple 101 and the left temple 103 are respectively connected to two sides of the frame 102, and a connection between the temple and the frame 102 may be a rotatable connection or a fixed connection. When a user wears the near-eye display device 1000, the frame 102 is located in front of eyes of the user, and the temple (the right temple 101 and the left temple 103) is placed on ears of the user. The foregoing structure of the mechanical part 100 is merely an example, and may be designed as required in another embodiment. For example, the mechanical part may be a headband or a helmet of a head-mounted display device.

The optical component 200 includes a lens 10 and an optical engine 20. The lens 10 is mounted to the frame 102 and is configured to be worn in front of a human eye. The lens 10 has light transmission, and the lens 10 has an optical waveguide 10A. For example, the optical waveguide 10A may be of a diffractive optical waveguide structure. In an implementation, all areas on the lens 10 are the optical waveguide 10A, that is, the optical waveguide 10A forms a lens of the near-eye display device 1000. In another implementation, the optical waveguide 10A may alternatively form only a part of the lens 10. The optical waveguide 10A has an in-coupling grating 11 and an out-coupling grating 12. The optical engine 20 is configured to project a light ray onto the optical waveguide 10A. The optical engine 20 projects a light ray onto the in-coupling grating 11, the light ray is coupled by the in-coupling grating 11 into the optical waveguide 10A, undergoes total internal reflection in the optical waveguide 10A, and then is emitted by the out-coupling grating 12. The out-coupling grating 12 emits the light ray, to generate a virtual image to enter a human eye.

In the implementation shown in FIG. 1, the optical engine 20 is located between a left lens 10L and a right lens 10R, and the optical engine 20 is located in a region on the top of the frame 102. Light rays emitted by the optical engine 20 include two paths of light rays. One path of light rays enters an optical waveguide 10A on the left lens 10L through an in-coupling grating 11 on the left lens 10L, and then is emitted by an out-coupling grating 12 on the left lens 10L to form a virtual image. The other path of light rays emitted by the optical engine 20 enters an optical waveguide 10A on the right lens 10R through an in-coupling grating 11 on the right lens 10R, and then is emitted by an out-coupling grating 12 on the right lens 10R to form a virtual image. In the implementation shown in FIG. 1, both the optical engine 20 and the two in-coupling gratings 11 are located at an intersection of the left lens 10L and the right lens 10R, that is, an adjacent region.

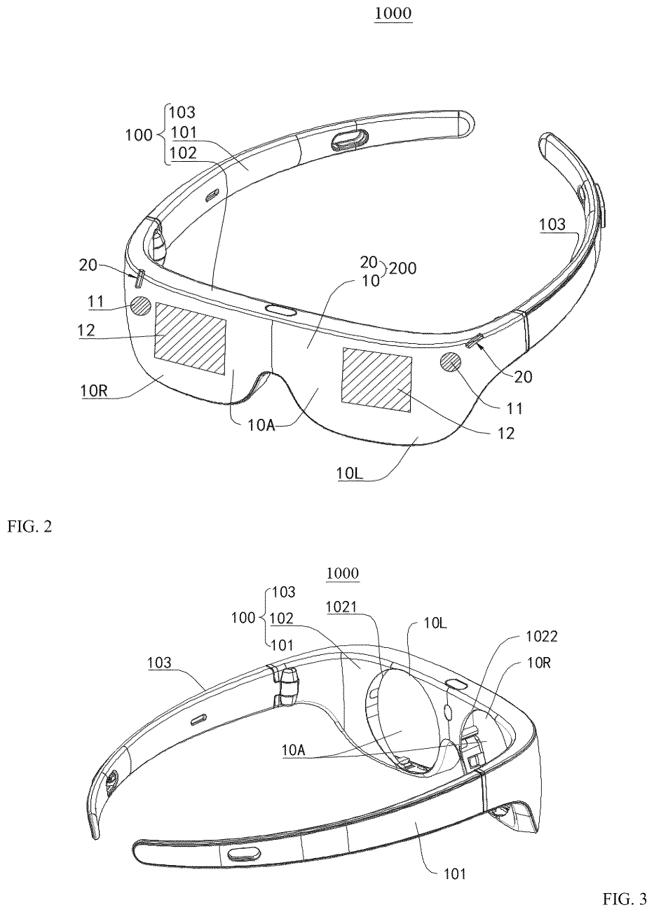

FIG. 2 is a diagram of a near-eye display device according to another implementation of this disclosure. As shown in FIG. 2, a mechanical part 100 of the near-eye display device provided in this implementation is the same as the mechanical part 100 in the implementation shown in FIG. 1. In the implementation shown in FIG. 2, there are two optical engines 20 in an optical component 200, and the two optical engines 20 are respectively located at positions at which two temples are connected to a frame or at nearby positions. One optical engine 20 is located at a connection position between a left temple 103 and a frame 102 or at a position that is on a frame 102 and that is close to the left temple 103, and the other optical engine 20 is located at a connection position between a right temple 101 and the frame 102 or at a position that is on the frame 102 and that is close to the right temple 101. One optical engine 20 is located above the left side of the left lens 10L, and the other optical engine 20 is located above the right side of the right lens 10R. In the implementation shown in FIG. 2, two in-coupling gratings 11 are respectively located in an upper left corner of the left lens 10L and an upper right corner of the right lens 10R. For the left lens 10L, a light ray emitted by the optical engine 20 enters an optical waveguide 10A on the left lens 10L through an in-coupling grating 11 on the left lens 10L, and then is emitted by an out-coupling grating 12 on the left lens 10L to form a virtual image. Similarly, for the right lens 10R, a light ray emitted by the optical engine 20 enters an optical waveguide 10A on the right lens 10R through an in-coupling grating 11 on the right lens 10R, and then is emitted by an out-coupling grating 12 on the right lens 10R to form a virtual image.

FIG. 3 is a diagram of the implementation shown in FIG. 1 or the implementation shown in FIG. 2 in another direction. As shown in FIG. 3, the frame 102 surrounds and defines two clear aperture regions 1021 and 1022. When the near-eye display device 1000 is in a worn state, the two clear aperture regions 1021 and 1022 exactly face a left eye and a right eye respectively. Further, the left lens 10L and the right lens 10R are respectively disposed in correspondence with the two clear aperture regions 1021 and 1022. Space surrounded by the clear aperture region 1021 or 1022 is the optical waveguide 10A (or a part of the optical waveguide 10A).

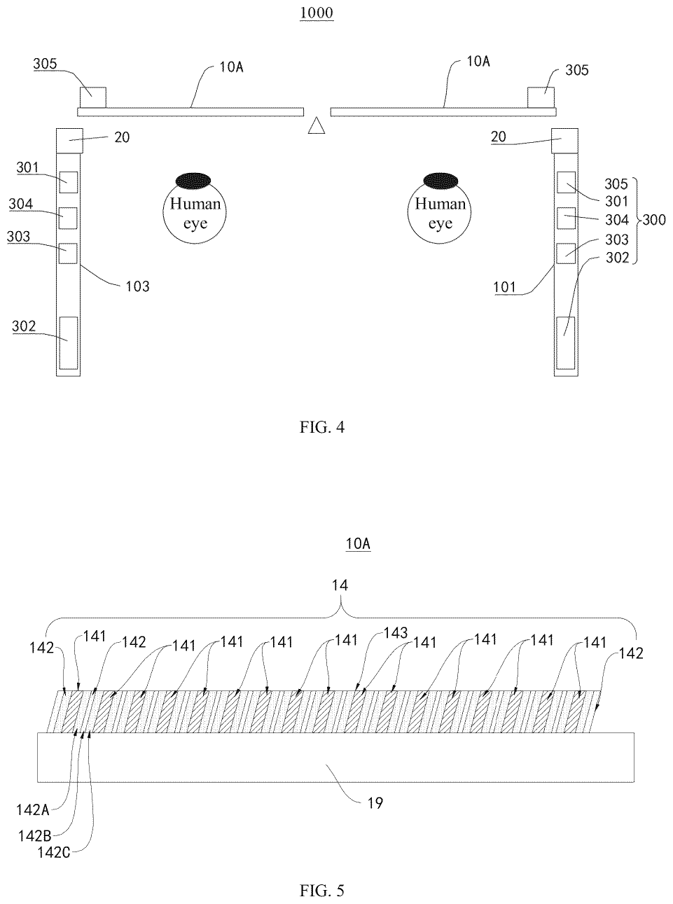

FIG. 4 is a planar diagram of a near-eye display device according to an implementation. As shown in FIG. 4, the near-eye display device 1000 further includes an electronic component 300. In an implementation, the electronic component 300 includes a controller 301, a battery 302, a voice apparatus 303, an antenna 304, a camera 305, and the like. There are two optical engines 20. One optical engine 20 is located at a position that is of the right temple 101 and that is close to an optical waveguide 10A on a lens, and the other optical engine 20 is located at a position that is of the left temple 103 and that is close to an optical waveguide 10A on a lens. In an implementation, there may also be two controllers 301. One controller 301 is located in the left temple 103 and is configured to drive the optical engine 20 mounted at the position of the left temple 103, and the other controller 301 is located in the right temple 101 and is configured to drive the optical engine 20 mounted at the position of the right temple 101. The controller 301 may be disposed on a mainboard of the near-eye display device 1000, and may be a central processing unit (CPU) of the near-eye display device 1000. The controller 301 may be configured to control the optical engine 20 to be on or off. In an implementation, the battery 302 is configured to supply power to the near-eye display device 1000. There are also two batteries 302, respectively located on the left temple 103 and the right temple 101. The battery 302 is located at one end that is of the temple and that is away from the lens, to facilitate charging. A charging interface may be disposed on the temple. In an implementation, there are also two voice apparatuses 303 and two antennas 304, and one voice apparatus 303 and one antenna 304 are disposed in each temple. The antenna 304 is configured to receive and send a wireless signal, for example, a WI-FI signal, a BLUETOOTH signal, or a mobile communication signal. The voice apparatus 303 may be configured to input or output sound, and is, for example, a microphone or a speaker. In an implementation, there are two cameras 305, one camera 305 is located at a left edge position of the left lens, and the other camera 305 is located at a right edge position of the right lens. The camera 305 may be connected to an image processor, and the camera 305 is configured to shoot an image, transmit the image to the image processor, and process image information by using the image processor. In another implementation, electronic components such as a memory, a sensor, and a positioning component may be further disposed in the near-eye display device 1000. For example, the memory is configured to store image information, and the sensor may include a power sensor (such as a gyroscope), a biological sensor, a temperature sensor, a humidity sensor, and the like. The positioning component may include a Global Positioning System (GPS) or BEIDOU positioning device.

### Solution 5: Coated Grating With a Gradient Refractive Index

According to an optical waveguide provided in a specific implementation of this disclosure, a light ray of each field of view generated by an optical engine is injected into the optical waveguide by using an in-coupling grating, and the light ray undergoes total internal reflection in the optical waveguide, is coupled out of the optical waveguide by an out-coupling grating, and enters a human eye for imaging. In addition, the optical waveguide allows a surrounding scene to pass through the optical waveguide and enter the human eye for imaging, so that a user can simultaneously observe a real scene and virtual information (image information). The optical waveguide provided in this disclosure may be used in a vehicle-mounted heads-up display (HUD), head-mounted AR glasses, and the like.

In an implementation, the in-coupling grating couples a light ray into the optical waveguide by using a diffraction effect, and the out-coupling grating may couple the light ray out of the optical waveguide also by using the diffraction effect. Therefore, how to improve in-coupling efficiency and coupling-out efficiency to improve optical utilization of an optical waveguide is a research direction in the industry.

In an implementation, diffraction efficiency and optical utilization can be improved by changing a refractive index of a grating. For example, a larger average refractive index and a higher refractive index modulation of a volume holographic grating are obtained by adjusting a formula of a holographic material, to obtain a volume holographic grating with different-refractive-index distribution. However, obtaining a desired average refractive index and refractive index modulation by changing the holographic material cannot achieve a desired effect. This is mainly due to a limitation in a characteristic of the holographic material. Further, the holographic material is usually made up of polymer monomers and inert polymers. These materials have a low refractive index (1.45 to 1.65), resulting in a low average refractive index of the materials. In addition, because the polymer monomer and the inert polymer are not completely separated in a process of light aggregation, a refractive index modulation of a grating structure made of a volume holographic material is also low (less than 0.15). Therefore, a volume holographic grating cannot obtain a desired average refractive index and a desired refractive index modulation.

In an implementation, this disclosure provides an optical waveguide. A grating structure of the optical waveguide is designed. Further, a structure of one period of the grating structure is designed as a layer structure that is disposed in a stacked manner in a vector direction of the grating structure and that has different refractive indexes. A refractive index of the grating structure changes through the design of different refractive indexes in one period of the grating structure, to improve diffraction efficiency and optical utilization of the optical waveguide.

Refer to FIG. 5. In an implementation, an optical waveguide 10A includes a waveguide substrate 19 and a grating structure 14 formed on the waveguide substrate 19. FIG. 5 schematically shows a specific position relationship between the waveguide substrate 19 and the grating structure 14 and structural components, and does not represent a specific structural form of the optical waveguide 10A. In the implementation shown in FIG. 5, the grating structure 14 protrudes from a surface of the waveguide substrate 19, the waveguide substrate 19 is in a flat-plate shape, and the surface of the waveguide substrate 19 may be planar in shape. The grating structure 14 may be an in-coupling grating, or may be an out-coupling grating or a relay grating. A light ray is coupled into the optical waveguide 10A through the grating structure 14, and can undergo total internal reflection in the waveguide substrate 19. The waveguide substrate 19 is a material with a high refractive index. For example, a refractive index of the waveguide substrate 19 is 1.38 to 2.6. A material of the waveguide substrate 19 may include a metal oxide. The material of the waveguide substrate 19 may be any one of magnesium fluoride (MgF₂), titanium dioxide (TiO₂), silicon nitride, gallium nitride, or a high-refractive resin material. The material of the waveguide substrate 19 may alternatively be a mixed material, and the mixed material includes a mixture of two or more of the foregoing materials. The waveguide substrate 19 may be of a single-layer structure, or the waveguide substrate 19 may be of a multi-layer structure, for example, a composite layer structure including different materials in all layers.

The grating structure 14 includes a plurality of core structures 141 and a film structure 142. A refractive index of the film structure 142 is different from a refractive index of the core structure 141, and the plurality of core structures 141 is sequentially arranged at intervals in a vector direction of the grating structure 14. The vector direction of the grating structure in FIG. 5 is a direction from left to right. There is a preset distance between adjacent core structures 141, and the film structure 142 is disposed within the preset distance range. In the vector direction of the grating structure 14, both sides of the core structure 141 are used for arrangement of the film structure 142. As shown in FIG. 5, a left side of a leftmost core structure 141 has the film structure 142, and a right side of a rightmost core structure 141 also has the film structure 142. In another implementation, the film structure 142 may be disposed only between adjacent core structures 141, that is, no film structure is disposed on the left side of the leftmost core structure 141 and no film structure is disposed on the right side of the rightmost core structure 142.

In the implementation shown in FIG. 5, a region between adjacent core structures 141 is filled with the film structure 142. In other words, there is no gap (or spacing, where no air exists inside the grating structure 14) in the region between the adjacent core structures 141. In this implementation, the grating structure 14 is a seamless structure continuously extending along the vector direction of the grating structure 14. Due to such as structure design, there is no air inside the grating structure 14, which helps ensure diffraction efficiency of the grating structure 14, and also helps ensure that the grating structure 14 is not affected by environmental factors. For example, dust, moisture, and the like in the air affect a function and life of the grating structure 14.

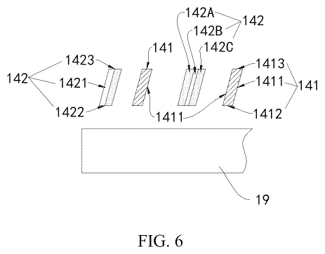

FIG. 6 is an exploded diagram of a part of the grating structure 14 and a part of the waveguide substrate 19 in FIG. 5, where the core structure 141 is separated from the film structure 142, to facilitate illustration of detailed structural characteristics of the core structure 141 and the film structure 142. With reference to FIG. 5 and FIG. 6, each core structure 141 includes a connection end 1412, a free end 1413, and a side surface 1411, the connection end 1412 is connected to the waveguide substrate 19, and the free end 1413 and the connection end 1412 are disposed opposite to each other in a height direction of the core structure 141. The height direction of the core structure 141 may be understood as a direction perpendicular to the surface of the waveguide substrate 19. The side surface 1411 is connected between the connection end 1412 and the free end 1413. The film structure 142 includes a film body 1421, a first end part 1422, and a second end part 1423, and the film body 1421 wraps the side surface 1411 of the core structure 141. It may also be understood that the film body 1421 is attached to the side surface 1411, and the film body 1421 and the side surface 1411 are in contact with each other and combined together. The first end part 1422 and the second end part 1423 are respectively located at two ends of the film body 1421, and the first end part 1422 is connected to the waveguide substrate 19. In an implementation, an end face of the second end part 1423 and an end face of the free end 1413 of the core structure 141 are coplanar, and the free ends 1413 of all the core structures 141 and the second end part 1423 of the film structure 142 jointly form an end face 143 of the grating structure 14.

In this solution, diffraction efficiency and optical utilization are improved by using different refractive indexes of the core structure 141 and the film structure 142 of the grating structure 14. The free end 1411 of the core structure 141 and the second end part 1423 of the film structure 142 jointly form the end face of the grating structure 14, so that diffraction efficiency of the grating structure 14 is better. The grating structure 14 has the core structure and the film structure with different refractive indexes only in the vector direction of the grating structure 14. In a height direction of the grating structure 14, because both the free end 1411 of the core structure 141 and the second end part 1423 of the film structure 142 are in an exposed state at a position of the end face of the grating structure 14, that is, the exterior of the core structure 141 in the grating height direction is not wrapped by the film structure 142, diffraction efficiency of the grating structure 14 can be ensured. If the free end of the core structure is wrapped by the film structure, a part that is of the film structure and that wraps the free end of the core structure generates a diffraction effect in the height direction of the grating structure. However, because diffraction in the height direction of the grating structure has a direction different from the vector direction of the grating structure, diffraction in the vector direction of the grating structure is negatively affected, that is, diffraction efficiency of the grating structure is reduced.

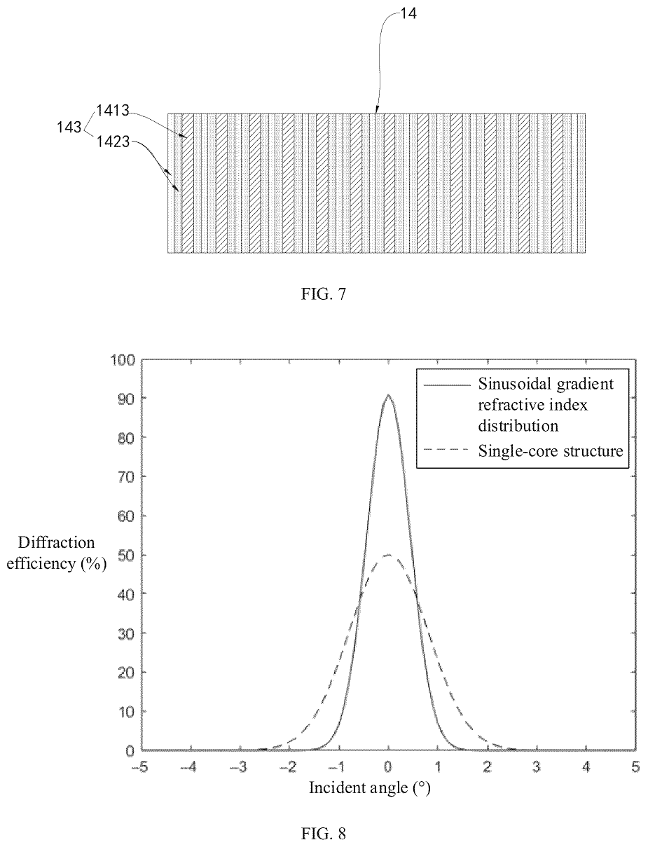

FIG. 7 is a diagram of an end face 143 of a grating structure 14. Refer to FIG. 7. The end face 143 of the grating structure 14 is a stripe-shaped architecture including an end face of a free end 1413 of a core structure 141 and an end face of a second end part 1423 of a film structure 142 that are alternately arranged. With reference to FIG. 5 and FIG. 7, the end face 143 of the grating structure 14 is of a planar architecture.

In an implementation, between adjacent core structures, the film structure includes at least three film layers, the at least three film layers are disposed in a stacked manner between the side surfaces of the adjacent core structures, the at least three film layers have different refractive indexes, and along the vector direction of the grating structure, refractive indexes of the at least three film layers exhibit a gradient trend of sine distribution.

As shown in FIG. 5 and FIG. 6, there are three layers of film structures 142 between adjacent core structures 141. Further, the three layers of film structures 142 are respectively a first film layer 142A, a second film layer 142B, and a third film layer 142C. The first film layer 142A, the second film layer 142B, and the third film layer 142C are disposed in a stacked manner between side surfaces 1411 of adjacent core structures 141 in the vector direction of the grating structure 14. The first film layer 142A and the third film layer 142C are respectively combined with side surfaces 1411 of adjacent core structure 141. Both the first film layer 142A and the third film layer 142C are in direct contact with the side surfaces 1411 of the core structures 141. The second film layer 142B is located between the first film layer 142A and the third film layer 142C.

The first film layer 142A, the second film layer 142B, and the third film layer 142C have different refractive indexes. The vector direction of the grating structure 14 may be understood as a direction in which a side surface 1411 of one of two adjacent core structures 141 faces a side surface 1411 of the other core structure 141. That the refractive index of the first film layer 142A, the refractive index of the second film layer 142B, and the refractive index of the third film layer 142C exhibit sine distribution may be understood as follows. A change trend of the three refractive indexes may be a change from large to small and then to large, or may be a change from small to large and then to small. There is a refractive index difference between the core structure 141 and the film structure 142, and there is also a refractive index difference between adjacent film layers inside the film structure 142.

In an implementation, both a refractive index of the first film layer 142A and a refractive index of the third film layer 142C are greater than a refractive index of the second film layer 142B, and the refractive index of the first film layer 142A may be equal to the refractive index of the third film layer 142C. In this implementation, a refractive index of the core structure 141 is greater than the refractive index of the first film layer 142A, and greater than the refractive index of the third film layer 142C. In this implementation, a refractive index range of each part structure may be but is not limited to the following description. A refractive index range of the core structure 141 may be 1.38 to 2.6, a refractive index range of the first film layer 142A and the third film layer 142C may be 1.38 to 2.6, and a refractive index range of the second film layer 142B may be 1.0 to 2.6.

In another implementation, both a refractive index of the first film layer 142A and a refractive index of the third film layer 142C are less than a refractive index of the second film layer 142B, and the refractive index of the first film layer 142A may be equal to the refractive index of the third film layer 142C. In this implementation, a refractive index of the core structure 141 is less than the refractive index of the first film layer 142A, and less than the refractive index of the third film layer 142C. In this implementation, a refractive index range of each part structure may be but is not limited to the following description. A refractive index range of the core structure 141 may be 1.0 to 2.6, a refractive index range of the first film layer 142A and the third film layer 142C may be 1.38 to 2.6, and a refractive index range of the second film layer 142B may be 1.38 to 2.6.

FIG. 8 is a diagram of curves showing a correspondence between an incident angle and diffraction efficiency for comparison between a grating structure with sinusoidal gradient refractive index distribution and a grating structure with a single-core structure. The grating structure with a single-core structure means design in which a refractive index of the grating structure is homogeneous, and in one period of the grating structure, there is only one single core structure, and a refractive index of the core structure is a fixed value. The grating structure with sinusoidal gradient refractive index distribution means that one period of the grating structure includes a core structure and a film structure, and refractive indexes of the core structure and the film structure are different, so that sinusoidal gradient refractive index distribution is generated. Refer to FIG. 8. It can be learned that, at a required incident angle (as shown in FIG. 8, an incident angle is near 0 degrees, and may be set to another incident angle as required), a grating with sinusoidal gradient refractive indexes may have higher diffraction efficiency and narrower full width at half maximum. This can meet a modulation requirement for incident efficiency at a specific angle, thereby improving light efficiency of an entire system.

In an implementation, between the adjacent core structures, the at least three film layers have different thicknesses, a film layer with a largest thickness is adjacent to the core structure, and a thickness of the core structure is greater than that of the film layer with the largest thickness. In the implementation shown in FIG. 5, the first film layer 142A and the third film layer 142C have a same thickness, and may be fabricated on side surfaces of core structures 141 by using a same coating process. From a fabrication perspective, this has advantages of easy implementation and working time reduction. The thickness of the second film layer 142B is not equal to that of the first film layer 142A, and in the specific implementation shown in FIG. 5, the thickness of the second film layer 142B is less than that of the first film layer 142A.

In an implementation, the thickness of the core structure 141 may alternatively be less than that of a film layer with a smallest thickness in the film structure 142, and the film layer with the smallest thickness is adjacent to the core structure 141. The thickness of the second film layer 142B may alternatively be greater than that of the first film layer 142A.

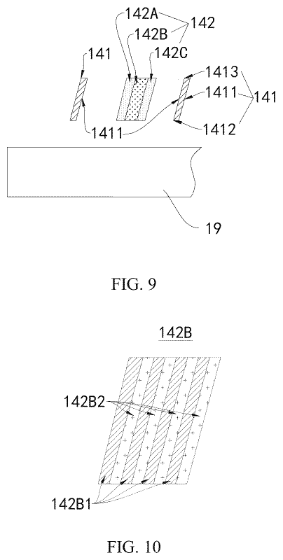

FIG. 9 is an exploded diagram of a part of a grating structure and a part of a waveguide substrate of an optical waveguide according to an implementation of this disclosure. Refer to FIG. 9. The thickness of the core structure 141 is less than that of the first film layer 142A, and is also less than that of the third film layer 142C, the thickness of the first film layer 142A may be equal to that of the third film layer 142C, and the second film layer 142B is a layer with the largest thickness in the film structure 142.

A thickness of the film structure 142 that is of the grating structure 14 provided in this disclosure and that covers the side surface 1411 of the core structure 141 may range from several angstroms to several nanometers. A film structure 142 between a core structure 141 and its adjacent core structure 141 forms one grating period.

Refer to FIG. 5. In one period between adjacent core structures 141, there are an odd number of layers of the film structure 142. For example, a quantity of layers of the film structure 142 is three, five, or seven. One layer located in the middle is a middle layer, and the remaining layers may be symmetrically distributed on two sides of the middle layer. For example, the first film layer 142A and the third film layer 142C are symmetrically distributed on two sides of the second film layer 142B. The symmetric distribution herein may be understood as symmetry in terms of physical sizes and symmetry in terms refractive indexes. Symmetric arrangement in terms of physical sizes helps achieve an advantage of low fabrication difficulty and ease of ensuring a yield rate, and symmetry in terms of refractive indexes helps achieve accurate control on diffraction efficiency and a corresponding incident angle.

In an implementation, a part of the film structure 142 between adjacent core structures 141 is of a seamless structure. It may be understood that a space between adjacent core structures 141 is filled with the film structure 142, and no gap is left. As shown in FIG. 5, the first film layer 142A and the third film layer 142C are attached to side surfaces 1411 of core structures 141, and two sides of the second film layer 142B are respectively directly connected to the first film layer 142A and the third film layer 142C.

The core structure 141 in the grating structure 14 provided in this disclosure may be a blazed grating or a slanted grating. Refractive indexes of any positions in the core structure 141 are the same, and the core structure 141 may be fabricated on the waveguide substrate 19 by using a nano-imprinting process or an etching process. The film structure 142 is formed by using a coating process. Further, a multi-layer film structure may be fabricated by using two or more coating processes. For example, in the implementation shown in FIG. 5, two coating processes are used in total, the first film layer 142A and the third film layer 142C are fabricated by using a 1^{st} first coating process, and the second film layer 142B is fabricated by using 2^{nd} coating process. The film structure 142 may alternatively be made by using another process such as atomic layer deposition (ALD), dip coating, or spin-coating.

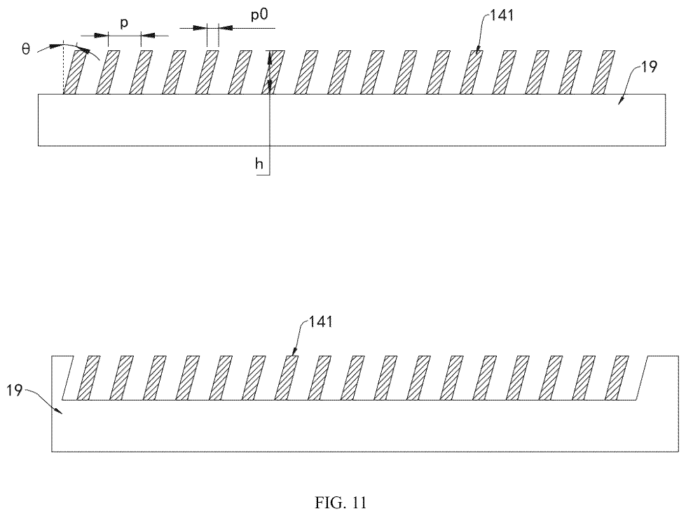

In an implementation, one film layer in the film structure 142 is divided into two types of sub-films with different refractive indexes: a first sub-film and a second sub-film, to obtain a target refractive index solution. Refer to FIG. 10. A process of fabricating the second film layer 142B is used as an example. A target refractive index of the second film layer 142 is N. However, it is difficult to directly fabricate a film layer to obtain a film layer with an accurate refractive index of N in terms of processes. Factors that affect fabrication may include material selection, film layer thickness control, and the like. In an implementation, the second film layer 142B includes multiple layers of first sub-films 142B1 and multiple layers of second sub-films 142B2 that are alternately arranged in one-to-one correspondence, a refractive index of the first sub-film 142B1 is N1, a refractive index of the second sub-film 142B2 is N2, a refractive index of the second film layer 142B that includes the multiple layers of first sub-films 142B1 and the multiple layers of second sub-films 142B2 is N, and N1<N<N2. The first sub-film 142B1 and the second sub-film 142B2 may be made of different materials, and may also have different thicknesses. The first sub-film 142B1 and the second sub-film 142B2 may be implemented by using a same fabrication process. Fabrication processes of the two film layers are simple and easy to implement, and refractive indexes of the two film layers are easy to control. The refractive index N of the finally obtained second film layer 142B can meet a design requirement.

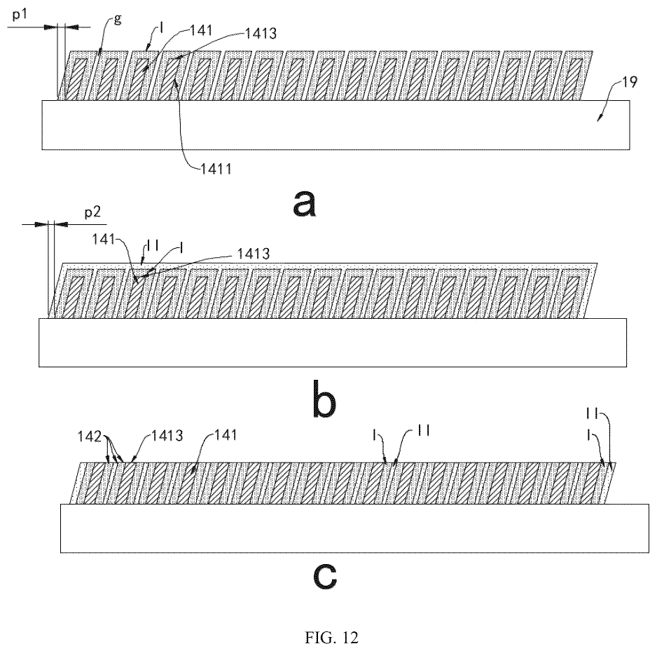

A method for fabricating the optical waveguide 10A shown in FIG. 5 is further described as follows with reference to FIG. 11 and FIG. 12.

Refer to FIG. 11. A core structure 141 is fabricated on a waveguide substrate 19. In an implementation, as shown in the upper part of FIG. 11, the core structure 141 protrudes from a surface of the waveguide substrate 19. In another implementation, as shown in the lower part of FIG. 11, the core structure 141 is embedded in the waveguide substrate 19, that is, the core structure 141 is formed in a concave part of the waveguide substrate 19. The core structure 141 may be fabricated on the waveguide substrate 19 by using an etching process. An obtained refractive index range of the core structure 141 fabricated by using the etching process may be 1.38 to 2.6. For example, when a material of the core structure 141 is MgF₂, a refractive index of the core structure 141 may be 1.38, or when a material of the core structure 141 is TiO₂, a refractive index of the core structure 141 may be 2.6. Alternatively, the core structure 141 may be fabricated on the waveguide substrate 19 by using a nano-imprinting technology, and an obtained refractive index range of a grating core layer may be approximately 1.4 to 2.6.

As shown in FIG. 11, in a specific implementation, a grating period p of a grating structure 14 ranges from 200 nanometers (nm) to 800 nm, a grating height h ranges from 5 nm to 3000 nm, and a grating tilt angle θ ranges from about 0° to 60°. In a typical embodiment, the period p is equal to 400 nm, the grating height h is 600 nm, the grating tilt angle θ is 55°, and a width p0 of the grating core layer is 130 nm.

Refer to FIG. 12. FIG. 12 includes diagram a, diagram b, and diagram c from top to bottom. The three diagrams are used to represent three steps of completing fabrication of the grating structure on a basis of the structure shown in FIG. 11.

As shown in diagram a in FIG. 12, after the core structure 141 is fabricated, the film structure is fabricated by using a coating process. First, a film layer I is fabricated on a surface of the core structure 141, where the film layer I wraps a periphery of the core structure 141. The core structure 141 is disposed on the waveguide substrate 19. In this state, both a side surface 1411 and a free end 1413 of the core structure 141 are covered by the film layer I. A thickness p1 of the film layer I may be 70 nm. In a region between adjacent core structures 141, a gap g is formed between film layers I. A refractive index of the film layer I may be 1.38 to 2.6.

As shown in diagram b in FIG. 12, after the film layer I is fabricated, a film layer II is fabricated. A method for fabricating the film layer II may be the same as a method for fabricating the film layer I, for example, the two film layers are fabricated by using the coating process. The film layer II completely covers the film layer I, and the gap g formed by the film layer I is also filled with the film layer II. After the film layer II is fabricated, in a height direction of the grating structure, the film layer I and the film layer II are sequentially stacked above the free end 1413 of the core structure 141. A refractive index of the film layer II may be 1.38 to 2.6. A thickness p2 of the film layer I may be 65 nm.

As shown in diagram c in FIG. 12, after the film layer II is fabricated, a film structure on the surface of the grating structure is polished to be flat by using a process such as chemical mechanical polishing (CMP), so that the free end 1413 of the core structure 141 is exposed. After a process of polishing, the film structure 142 forms a state in which the core structure 141 is not completely wrapped. The film structure 142 forms a film body and a first end part and a second end part that are respectively located at two ends of the film body. The second end part and the free end 1413 of the core structure 141 are coplanar, and the free ends of all the core structures and the second end part of the film structure jointly form an end face of the grating structure.

In an implementation, when the refractive index of the core structure is 1.9, the refractive index of the film layer I in the film structure is 2.1, and the refractive index of the film layer II is 2.3, an average refractive index n=2.1 and a refractive index modulation Δn=0.4 may be obtained. The grating structure obtained in this solution has an advantage of high diffraction efficiency.

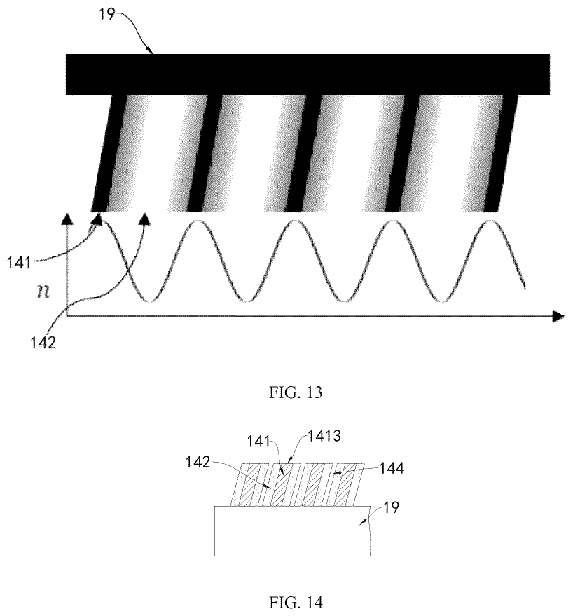

Refer to FIG. 13. In an implementation, a film structure 142 having a film layer with a gradient refractive index may be coated on a basis of the core structure 141, so that good angle and wavelength selection can be obtained. An surface relief grating (SRG) structure (that is, the core structure 141) with a high refractive index is obtained on the waveguide substrate 19 by using an etching process or a nano-imprinting process. A refractive index of the SRG grating structure (that is, the core structure 141) may reach 2.0 or even higher. For example, when TiO₂ is used as the waveguide substrate 19, a highest refractive index of the SRG grating (that is, the core structure 141) obtained by using the etching process may reach 2.6. Then, the film structure 142 is formed by using a multi-layer coating process, where a refractive index may gradually change. A thickness of each coating layer may be several angstroms to several nanometers, and a lowest refractive index may be an air layer. In this case, An may reach a maximum of 1.6. When the core structure 141 has a high refractive index (for example, a refractive index range is from 1.38 to 2.6), there is a film structure 142 including multiple layers of materials between two core structures 141, and refractive index distribution of the film structure 142 is sine change distribution, as shown by a sine curve in FIG. 13: The refractive index gradually decreases and then gradually increases. A lowest refractive index of the film structure 142 with a gradient refractive index may reach 1.38, and a highest refractive index may reach 2.6. When the core structure 141 has a low refractive index (for example, a refractive index range is from 1.38 to 2.6), a refractive index change distribution between two core structures 141 is still sine distribution, and the refractive index gradually increases and then gradually decreases. This solution can obtain the following benefits. An average refractive index and a refractive index modulation of the grating can be greatly improved, the average refractive index may reach 2.0 or higher, and An may reach 1.0 or higher, so that a parameter range can be expanded, to provide a proper optimization space for subsequent optical waveguide design.

Similarly, in another implementation, if the core structure 141 is fabricated by using a low-refractive material, and then the film structure 142 is processed by using a high-refractive material, a similar grating structure whose refractive index change distribution is still sinusoidal distribution can be obtained.

Refer to FIG. 14. In an implementation, there is a film gap 144 in a middle position of a film structure 142 between adjacent core structures 141. The gap 144 may be air, and a refractive index of air is 1. In this implementation, a refractive index of the core structure 141 is greater than a refractive index of the film structure 142, and a refractive index of the film structure 142 is greater than 1.38. In this way, between adjacent core structures 141, refractive indexes of the grating structure exhibit a gradient trend of sine distribution. In this implementation, the film structure 142 may be formed on a surface of the core structure 141 through one-time coating.

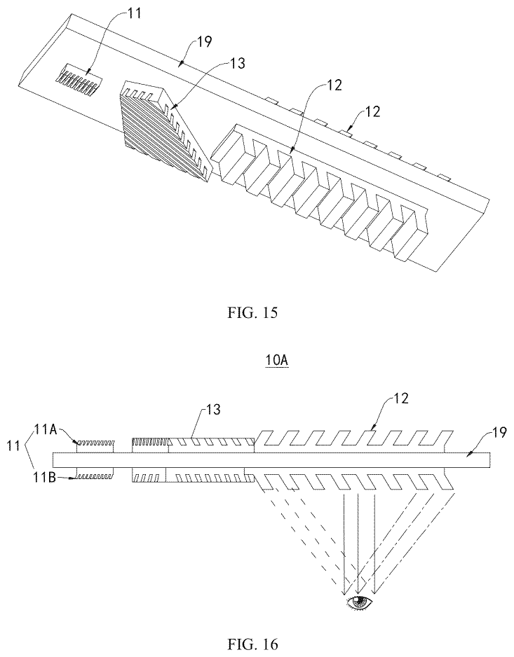

FIG. 15 is a 3D diagram of an optical waveguide according to an implementation of this disclosure, and schematically shows a grating structure disposed on a surface of a waveguide substrate 19. FIG. 15 merely schematically shows that an in-coupling grating 11, a relay grating 13, and an out-coupling grating 12 are disposed on the waveguide substrate 19, and does not limit specific structures and position relationships of the in-coupling grating 11, the relay grating 13, and the out-coupling grating 12, and a connection relationship, a position relationship, and the like between the three gratings and the waveguide substrate 19. In the implementation shown in FIG. 15, out-coupling gratings 12 are distributed on two sides of the waveguide substrate 19, that is, the out-coupling gratings 12 are disposed on both a top surface and a bottom surface of the waveguide substrate 19. A grating tilt angle of the out-coupling grating 12 located on the top surface of the waveguide substrate 19 may be different from a grating tilt angle of the out-coupling grating 12 located on the bottom surface of the waveguide substrate 19. In this way, the out-coupling grating 12 may diffract light rays in different directions, so that more light rays are coupled out of the waveguide substrate 19, thereby improving diffraction efficiency.

FIG. 16 is a planar diagram of an optical waveguide according to an implementation of this disclosure. Refer to FIG. 16. In an implementation, the in-coupling grating 11 includes a first in-coupling structure 11A and a second in-coupling structure 11B, the first in-coupling structure 11A and the second in-coupling structure 11B are disposed opposite to each other and are respectively located on the top surface and the bottom surface of the waveguide substrate 19, and the first in-coupling structure 11A and the second in-coupling structure 11B have different grating tilt angles. The first in-coupling structure 11A and the second in-coupling structure 11B may diffract light rays in different directions, so that more light rays are coupled into the waveguide substrate 19. That is, the first in-coupling structure 11A and the second in-coupling structure 11B are combined to achieve high diffraction efficiency within a large angle range.

The first in-coupling structure 11A and the second in-coupling structure 11B may be of different grating structures, and may have different grating parameters such as grating heights and grating duty cycles. The first in-coupling structure 11A and the second in-coupling structure 11B may use the grating structure provided in the implementation shown in FIG. 5, FIG. 13, or FIG. 14. The first in-coupling structure 11A and the second in-coupling structure 11B may have different grating core layers (that is, core structures may be different). The first in-coupling structure 11A and the second in-coupling structure 11B may have different film structures (that is, grating coating layers), or may have a same film structure (that is, grating coating layer).

A refractive index of a core structure of the first in-coupling structure 11A may be higher than a refractive index of a core structure of the second in-coupling structure 11B, and a refractive index of a film structure of the first in-coupling structure 11A may be higher than a refractive index of a film structure of the second in-coupling structure 11B. In a specific implementation, the first in-coupling structure 11A has a core structure with a high refractive index (for example, a refractive index range of the core structure is from 1.9 to 2.3), and a film structure of the first in-coupling structure 11A is also made of a material with a high refractive index. For example, a refractive index range of the film structure is from 2.1 to 2.6. The first in-coupling structure 11A can respond to a light ray within an angle range of [−20°, 10°]. The second in-coupling structure 11B uses a core structure with a low refractive index (for example, a refractive index range of the core structure is from 1.5 to 1.9), and a refractive index range of a film structure of the second in-coupling structure 11B is from 1.7 to 2.1. The second in-coupling structure 11B can respond to a light ray within an angle range of [10°, 20°]. The first in-coupling structure 11A and the second in-coupling structure 11B act together, and can respond to a light ray in an incident angle range of [−20°, 20°].

In the implementation shown in FIG. 16, the out-coupling grating 12 also has grating structures distributed on the top surface and the bottom surface of the waveguide substrate 19. In an implementation, both the out-coupling grating 12 and the in-coupling grating 11 use the grating structure provided in the implementation shown in FIG. 5, FIG. 13, or FIG. 14. The out-coupling grating 12 and the in-coupling grating 11 may have different film structures, for example, different materials, different refractive indexes, and different thicknesses.

In one case, in the implementation shown in FIG. 16, a narrow angular bandwidth can be achieved, so that the optical waveguide can meet a specific design requirement. Further, for the out-coupling grating 12, when a grating region needs to modulate light only in a specific direction, that is, couple light in the specific direction to the human eye, a narrower angular bandwidth is required in this case. Higher diffraction efficiency can be obtained at a specific angle. As shown in FIG. 16, the human eye sees light rays projected from a left side of the out-coupling grating 12 (three dashed lines on the left side of the out-coupling grating 12 schematically represent light rays projected from the left side of the out-coupling grating 12), and only a part on the left side of the out-coupling grating 12 needs to couple the light rays. Therefore, this part of the out-coupling grating needs to have high diffraction efficiency for this emergent angle. An angular bandwidth of diffraction efficiency required for the part of the grating is narrow. Similarly, for light rays in a middle part (three solid lines in the middle position of the out-coupling grating 12 schematically represent light rays projected from the middle position of the out-coupling grating 12), diffraction efficiency of a middle region of the out-coupling grating also requires a narrow angular bandwidth, to obtain high diffraction efficiency. For light rays on a right side of the out-coupling grating (three dash-dotted lines on the right side of the out-coupling grating 12 represent light rays projected from the right side of the out-coupling grating 12), a narrow bandwidth is required for light rays coupled out from the right side of the out-coupling grating, to obtain high diffraction efficiency.

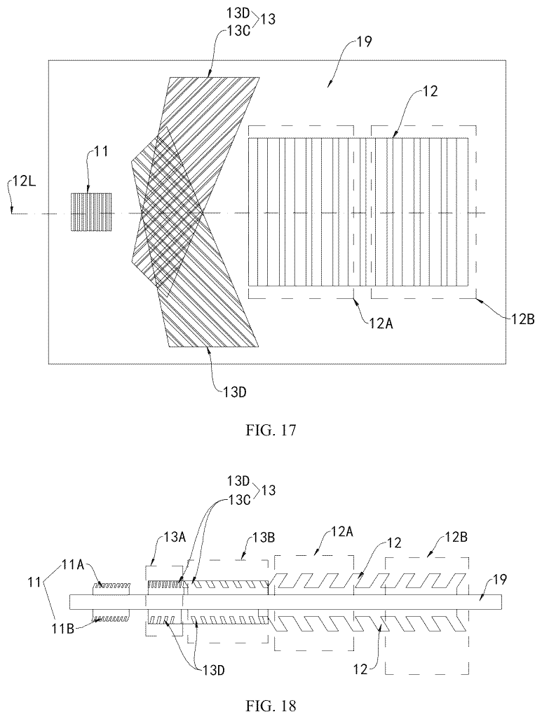

FIG. 17 is a planar diagram of an optical waveguide according to an implementation of this disclosure. In the implementation shown in FIG. 17, a relay grating 13 is located between an in-coupling grating 11 and an out-coupling grating 12, and relay gratings 13 are distributed on a top surface and a bottom surface of the waveguide substrate 19. FIG. 17 shows the relay gratings 13 distributed on the top surface and the bottom surface. The relay grating 13 on the top surface and the relay grating 13 on the bottom surface may have a same structural form and different grating tilt angles, the relay grating 13 on the top surface and the relay grating 13 on the bottom surface may form a symmetric distribution architecture that uses a central axis 12L as a center, and the central axis 12L may be understood as a connection line between a center of the in-coupling grating 11 and a center of the out-coupling grating 12.

As shown in FIG. 17, in an implementation, the out-coupling grating 12 uses the grating structure provided in the implementation shown in FIG. 5, FIG. 13, or FIG. 14. The out-coupling grating 12 includes a first region 12A and a second region 12B, and the first region 12A is closer to the in-coupling grating 11 than the second region 12B. A refractive index difference between a core structure and a film structure of the out-coupling grating 12 in the first region 12A is a first value, a refractive index difference between a core structure and a film structure of the out-coupling grating 12 in the second region 12B is a second value, and the first value is less than the second value. In FIG. 17, rectangular dashed-line boxes are used to represent the first region 12A and the second region 12B. The two rectangular dashed-line boxes in FIG. 17 merely schematically represent a position relationship between the first region 12A and the second region 12B, and do not represent specific structural forms and sizes of outer contours of the first region 12A and the second region 12B. The first region 12A and the second region 12B may be adjacent to each other, that is, boundaries of the first region 12A and the second region 12B are in contact with each other, or are referred to as having a common boundary. The first region 12A and the second region 12B may also be disposed at an interval, like the arrangement shown in FIG. 17, that is, the first region 12A and the second region 12B are separated by using another part of an out-coupling grating.

Refer to FIG. 17 and FIG. 18. In an implementation, the relay grating 13 includes a first relay structure 13C and a second relay structure 13D, the first relay structure 13C and the second relay structure 13D are respectively disposed on a top surface and a bottom surface of the waveguide substrate 19, and the first relay structure 13C and the second relay structure 13D may have different vector directions. The first relay structure 13C and the second relay structure 13D are disposed to have different vector directions, so that more light ray can enter the out-coupling grating 12, thereby improving optical utilization.

In an implementation, for the relay grating 13, film structures at different positions have different coating parameters, and the coating parameters may be but are not limited to a refractive index, a thickness, a density, and the like.

As shown in FIG. 18, in an implementation, the relay grating 13 uses the grating structure provided in the implementation shown in FIG. 5, FIG. 13, or FIG. 14. The relay grating 13 includes a third region 13A and a fourth region 13B, and the third region 13A is closer to the in-coupling grating 11 than the fourth region 13B. A refractive index difference between a core structure and a film structure of the relay grating 13 in the third region 13A is a third value, and a refractive index difference between a core structure and a film structure of the relay grating 13 in the fourth region 13B is a fourth value, and the third value is less than the fourth value. In this implementation, the out-coupling grating 12 may also be an architecture of the out-coupling grating 12 shown in FIG. 17, that is, the out-coupling grating 12 may also include a first region 12A and a second region 12B. A refractive index difference between a core structure and a film structure of the out-coupling grating 12 in the first region 12A is a first value, a refractive index difference between a core structure and a film structure of the out-coupling grating 12 in the second region 12B is a second value, and the first value is less than the second value. In this solution, the refractive index difference (that is, the fourth value) between the core structure and the film structure in the fourth region 13B of the relay grating 13 is less than the first value.

In a specific implementation, in the third region 13A, a refractive index of the core structure of the relay grating 13 is 2.4, a refractive index of the film structure is 1.9, and the third value (that is, the refractive index difference between the core structure and the film structure of the relay grating 13 in the third region 13A) is 0.5. In the fourth region 13B, a refractive index of the core structure of the relay grating 13 is 2.4, a refractive index of the film structure is 1.5, and the fourth value (that is, the refractive index difference between the core structure and the film structure of the relay grating 13 in the fourth region 13B) is 0.9. Grating efficiency in the third region 13A is less than that in the fourth region 13B.

In an implementation, in a vector direction of the relay grating 13, a refractive index difference between the core structure and the film structure exhibits a gradient trend, the refractive index difference gradually increases, and a refractive index of the relay grating also gradually increases.

In summary, in this disclosure, to obtain uniform brightness distribution, diffraction efficiency of the optical waveguide needs to be continuously improved. For example, the diffraction efficiency needs to have an increasing trend in a direction of extending from the in-coupling grating to the out-coupling grating. In order to gradually improve diffraction efficiency, in this disclosure, the refractive index difference may gradually increase, to improve a grating diffraction rate. Increasing the refractive index also helps improve grating diffraction efficiency.

At least a part of the in-coupling grating 11, the relay grating 13, and the out-coupling grating 12 in the implementations shown in FIG. 15, FIG. 16, FIG. 17, and FIG. 18 may include the grating structure provided in the implementations shown in FIG. 5, FIG. 13, or FIG. 14.

An optical waveguide provided in an implementation of this disclosure is used in a near-eye display device as a medium for light ray propagation. The optical waveguide includes a waveguide substrate and an in-coupling grating and an out-coupling grating that are formed on the waveguide substrate. After the in-coupling grating couples a light ray transmitted by an optical engine into the optical waveguide, total internal reflection propagation of the light ray needs to be performed in the waveguide substrate. In order to achieve a large field of view, a refractive index of the waveguide substrate needs to be increased. Therefore, to obtain an image with a good field of view and a good optical effect, the waveguide substrate needs to have a high refractive index. For the waveguide substrate, a larger refractive index indicates a larger weight, but a larger weight affects comfort of wearing the near-eye display device. For design of the optical waveguide, how to reduce a weight is an important research and development direction.

In an implementation, in this disclosure, a medium layer with a low refractive index and grating structures formed on a top surface and a bottom surface of the medium layer jointly form the waveguide substrate, and total internal reflection propagation of a light ray is performed by using the grating structures formed on the top surface and the bottom surface of the medium layer. The grating structure described herein is not an in-coupling grating, an out-coupling grating, or a relay grating. A function of the grating structure is merely to achieve total internal reflection propagation of a light ray in the waveguide substrate. The medium layer with a low refractive index has a lightweight advantage, and an overall weight of the waveguide substrate including the medium layer with a low refractive index and the grating structures formed on the top surface and the bottom surface of the medium layer may be controlled to be within a small range.

In the description of this disclosure, it should be understood that the term “and/or” indicates that two solutions may exist separately or may both exist. For example, “A and/or B” includes three solutions: solution A, solution B, and solutions A and B.

The terms “center”, “longitudinal”, “transverse”, “length”, “width”, “thickness”, “up”, “down”, “front”, “back”, “left”, “right”, “vertical”, “horizontal”, “top”, “bottom”, “internal”, “outside”, “clockwise”, “counterclockwise”, “axial”, “radial”, “circular”, or other orientation or position relationships indicated by the terms are based on an orientation or position relationship shown in the accompanying drawings, which is merely intended to facilitate description of this disclosure and simplify the description, but is not intended to indicate or imply that a specified apparatus or element must have a specific orientation, and be constructed and operated in a specific orientation. Therefore, this shall not be construed as a limitation on the present disclosure.

In addition, the terms “first” and “second” are merely intended for a purpose of description, and shall not be understood as an indication or implication of relative importance or implicit indication of the number of indicated technical features. Therefore, a feature limited by “first” or “second” may explicitly or implicitly include at least one of the features. In the descriptions about this disclosure, “a plurality of” means at least two, for example, two or three, unless otherwise limited.

In this disclosure, unless otherwise specified and limited, the terms such as “mount”, “link”, “connect”, and “fasten” should be understood broadly. For example, the term “connect” may be a fixed connection, may be a detachable connection, or may be integration, may be a mechanical connection or may be an electrical connection or a connection capable of achieving mutual communication, or may be a direct connection, may be an indirect connection implemented by using an intermediate medium, or may be communication inside two elements or an interaction relationship between two elements, unless otherwise limited. A person of ordinary skill in the art may understand specific meanings of the foregoing terms in this disclosure based on a specific case.

In this disclosure, unless otherwise specified and limited, when a first feature is “above” or “below” a second feature, the first feature may be in direct contact with the second feature, or the first feature may be in indirect contact with the second feature through an intermediate medium. In addition, that a first feature is “above” a second feature may be that the first feature is directly above or obliquely above the second feature, or merely indicates that a horizontal height of the first feature is greater than a horizontal height of the second feature. That a first feature is “below” a second feature may be that the first feature is directly below or obliquely below the second feature, or merely indicates that a horizontal height of the first feature is less than a horizontal height of the second feature.

In this disclosure, the terms “an embodiment”, “some embodiments”, “example”, “specific example”, or “some examples” mean that specific characteristics, structures, materials, or features described with reference to the embodiment or example are included in at least one embodiment or example of this disclosure. In the specification, the foregoing example expressions of the terms are not necessarily with respect to a same embodiment or example. In addition, the described specific features, structures, materials, or characteristics may be combined in an appropriate manner in any one or more of the embodiments or examples. In addition, persons skilled in the art may integrate or combine different embodiments or examples or characteristics of different embodiments or examples described in this specification, provided that they do not conflict with each other.

The foregoing descriptions are merely specific implementations of this disclosure, but are not intended to limit the protection scope of this disclosure. Any variation or replacement readily figured out by a person skilled in the art within the technical scope disclosed in this disclosure shall fall within the protection scope of this disclosure. Therefore, the protection scope of this disclosure shall be subject to the protection scope of the claims.

1. An optical waveguide comprising:
a waveguide substrate; and
a grating structure disposed on the waveguide substrate and comprising:
a grating structure end face;
core structures sequentially arranged at intervals in a vector direction of the grating structure, wherein all of the core structures have a first refractive index and wherein each of the core structures comprises:
a connection end coupled to the waveguide substrate and disposed in a height direction of a corresponding core structure;
a free end disposed opposite to the connection end in the height direction; and
a side surface disposed between the connection end and the free end; and
a first film structure having a second refractive index that is unequal to the first refractive index and comprising:
a film body configured to wrap the side surface and comprising a first film body end and a second film body end;
a first end part disposed at the first film body end and coupled to the waveguide substrate; and
a second end part that is disposed at the second film body end and that is coplanar with the free end,
wherein the free end of all the core structures and the second end part jointly define the grating structure end face.

2. The optical waveguide of claim 1, wherein the free end comprises a free end face, wherein the second end part comprises a second end part end face, and wherein the free end face and the second end part end face are coplanar.

3. The optical waveguide of claim 1, wherein the first film structure is disposed between adjacent core structures and comprises at least three film layers disposed in a stack between side surfaces of the adjacent core structures, wherein the at least three film layers have unequal refractive indexes, and wherein refractive indexes of the at least three film layers exhibit a gradient trend of sine distribution along the vector direction.

4. The optical waveguide of claim 3, wherein the at least three film layers have different thicknesses, and wherein either a first film layer with a largest thickness is adjacent to a core structure and a thickness of the adjacent core structure is greater than the largest thickness, or a second film layer with a smallest thickness is adjacent to a core structure and the thickness of the adjacent core structure is less than the smallest thickness.

5. The optical waveguide of claim 3, wherein one of the at least three film layers comprises first multiple layers of first sub-films and second multiple layers of second sub-films that are alternately arranged in a one-to-one correspondence, wherein a third refractive index of the first sub-film is N1, wherein a fourth refractive index of the second sub-film is N2, wherein a fifth refractive index of the one of the at least three film layers is N, and wherein N1<N<N2.

6. The optical waveguide of claim 1, wherein a part of the first film structure is a seamless structure disposed between adjacent core structures.

7. The optical waveguide of claim 1, wherein the first film structure is disposed between adjacent core structures and comprises a gap at a middle position.

8. The optical waveguide of claim 1, wherein the waveguide substrate comprises a top surface and a bottom surface, wherein the optical waveguide further comprises an in-coupling grating, and wherein the in-coupling grating comprises:
a first in-coupling structure disposed on the top surface and comprising first grating tilt angles; and
a second in-coupling structure disposed opposite to the first in-coupling structure, disposed on the bottom surface and comprising second grating tilt angles not equal to the first grating tilt angles, and wherein at least a part of the in-coupling grating further defines the grating structure.

9. The optical waveguide of claim 8, wherein each of the first in-coupling structure and the second in-coupling structure further define the grating structure, wherein a third refractive index of a first core structure of the first in-coupling structure is greater than a fourth refractive index of a second core structure of the second in-coupling structure, and wherein a fifth refractive index of a second film structure of the first in-coupling structure is greater than a sixth refractive index of a third film structure of the second in-coupling structure.

10. A near-eye display device comprising:
an optical engine configured to project a light ray; and
an optical waveguide configured to receive the light ray and comprising:
a waveguide substrate; and
a grating structure disposed on the waveguide substrate and comprising:
a grating structure end face;
core structures sequentially arranged at intervals in a vector direction of the grating structure, wherein all of the core structures have a first refractive index, and wherein each of the core structures comprises:
a connection end coupled to the waveguide substrate and disposed in a height direction of a corresponding core structure;
a free end disposed opposite to the connection end in the height direction; and
a side surface disposed between the connection end and the free end; and
a first film structure having a second refractive index that is unequal to the first refractive index and comprising:
a film body configured to wrap the side surface and comprising a first film body end and a second film body end;
a first end part disposed at the first film body end and coupled to the waveguide substrate; and
a second end part that is disposed at the second film body end and that is coplanar with the free end,
wherein the free end of all the core structures and the second end part jointly define the grating structure end face, and
wherein the grating structure end face is configured to emit the light ray to generate an image.

11. The near-eye display device of claim 10, wherein the free end comprises a free end face, wherein the second end part comprises a second end part end face, and wherein the free end face and the second end part end face are coplanar.

12. The near-eye display device of claim 10, wherein the first film structure is disposed between adjacent core structures and comprises at least three film layers disposed in a stack between side surfaces of the adjacent core structures, wherein the at least three film layers have unequal refractive indexes, and wherein refractive indexes of the at least three film layers exhibit a gradient trend of sine distribution along the vector direction.

13. The near-eye display device of claim 12, wherein the at least three film layers have different thicknesses, and wherein either:
a first film layer with a largest thickness is adjacent to a core structure and a thickness of the adjacent core structure is greater than the largest thickness; or
a second film layer with a smallest thickness is adjacent to a core structure and the thickness of the adjacent core structure is less than the smallest thickness.

14. The near-eye display device of claim 12, wherein one of the at least three film layers comprises first multiple layers of first sub-films and second multiple layers of second sub-films that are alternately arranged in a one-to-one correspondence, wherein a third refractive index of the first sub-film is N1, wherein a fourth refractive index of the second sub-film is N2, wherein a fifth refractive index of the one of the at least three film layers is N, and wherein N1<N<N2.

15. The near-eye display device of claim 10, wherein a part of the first film structure is a seamless structure disposed between adjacent core structures.

16. The near-eye display device of claim 10, wherein the first film structure is disposed between adjacent core structures and comprises a gap at a middle position.

17. The near-eye display device of claim 10, wherein the waveguide substrate comprises a top surface and a bottom surface, wherein the optical waveguide further comprises an in-coupling grating, and wherein the in-coupling grating comprises:
a first in-coupling structure disposed on the top surface and comprising first grating tilt angles; and
a second in-coupling structure disposed opposite to the first in-coupling structure, disposed on the bottom surface, and comprising second grating tilt angles that are not equal to the first grating tilt angles, and wherein the wherein at least a part of the in-coupling grating further defines the grating structure.

18. The near-eye display device of claim 17, wherein each of the first in-coupling structure and the second in-coupling structure further define the grating structure, wherein a third refractive index of a first core structure of the first in-coupling structure is greater than a fourth refractive index of a second core structure of the second in-coupling structure, and wherein a fifth refractive index of a second film structure of the first in-coupling structure is greater than a sixth refractive index of a third film structure of the second in-coupling structure.

19. A near-eye display device comprising:
a mechanical part comprising a frame; and
an optical component comprising:
an optical engine configured to project a light ray; and
a lens mounted on the frame and comprising an optical waveguide configured to receive the light ray and comprising:
a waveguide substrate; and
a grating structure disposed on the waveguide substrate and comprising:
a grating structure end face;
core structures sequentially arranged at intervals in a vector direction of the grating structure, wherein all of the core structures have a first refractive index, and wherein each of the core structures comprises:
a connection end coupled to the waveguide substrate and disposed in a height direction of a corresponding core structure;
a free end disposed opposite to the connection end in the height direction; and
a side surface disposed between the connection end and the free end; and
a film structure having a second refractive index that is unequal to the first refractive index and comprising:
a film body configured to wrap the side surface and comprising a first film body end and a second film body end;
a first end part disposed at the first film body end and coupled to the waveguide substrate; and
a second end part that is disposed at the second film body end and that is coplanar with the free end,
wherein the free end of all the core structures and the second end part jointly form the grating structure end face, and wherein the grating structure end face is configured to emit the light ray to generate an image.

20. The near-eye display device of claim 19, wherein the free end comprises a free end face, wherein the second end part comprises a second end part end face, and wherein the free end face and the second end part end face are coplanar.
